(19) United States
(12) Patent Application Publication
(10) Pub. No.: US 2026/0271523 A1
(43) Pub. Date: Sep. 10, 2026

(54) DISPLAY DEVICE, MANUFACTURING METHOD OF THE DISPLAY DEVICE AND ELECTRONIC DEVICE COMPRISING THE SAME

(71) Applicant: Samsung Display Co., Ltd., Yongin-si (KR)

(72) Inventors: Keun Woo KIM, Yongin-si (KR); Hyun Eok SHIN, Yongin-si (KR)

(21) Appl. No.: 19/383,166

(22) Filed: Nov. 7, 2025

(30) Foreign Application Priority Data
Jan. 16, 2025 (KR) 10-2025-0006554

(51) Int. Cl. H10K 59/121; H10K 59/12; H10K 59/35

(52) U.S. Cl. CPC H10K 59/1213; H10K 59/1201; H10K 59/1216; H10K 59/353

(57) ABSTRACT

Provided is a display device, manufacturing method of the display device, and electronic device comprising the same, the display device including a substrate, a first switch element including a first active layer including a first channel portion above the substrate, a first electrode at one side of the first channel portion, a second electrode at another side of the first channel portion, a gate electrode overlapping the first channel portion in a thickness direction of the substrate, and a first capacitor including a first capacitor electrode extending from a first electrode of the first switch element, and a second capacitor electrode extending from the gate electrode of the first switch element and overlapping the first capacitor electrode in the thickness direction.

### CROSS-REFERENCE TO RELATED APPLICATION

The present application claims priority to, and the benefit of, Korean Patent Application No. 10-2025-0006554, filed on Jan. 16, 2025, in the Korean Intellectual Property Office, the entire disclosure of which is incorporated herein by reference.

### BACKGROUND

### 1. Field

The present disclosure relates to a display device, a manufacturing method of the display device, and an electronic device comprising the same.

### 2. Description of the Related Art

A head-mounted display (HMD) is an image display device that is worn on a user's head in the form of glasses or helmets to form a focus at a close distance in front of the user's eyes. The head-mounted display may implement virtual reality (VR) or augmented reality (AR).

The head-mounted display magnifies an image displayed on a small display device by using a plurality of lenses, and displays the magnified image. Therefore, the display device applied to the head-mounted display may suitably provide high-resolution images, for example, images with a resolution of about 1500 PPI (Pixels Per Inch) or higher. To this end, an organic light-emitting diode on silicon (OLEDoS), which is a high-resolution small organic light-emitting display device, is used as the display device applied to the head-mounted display. The OLEDoS is an image display device in which an organic light-emitting diode (OLED) is located on a semiconductor wafer substrate including complementary metal oxide semiconductor (CMOS). However, because the OLEDoS uses a relatively expensive semiconductor wafer substrate, a display device capable of providing high-resolution images may suitably replace it.

### SUMMARY

Aspects of the present disclosure provide a display device capable of providing high-resolution images.

Aspects of the present disclosure also provide a head-mounted display capable of providing high-resolution images.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to various embodiments of the present disclosure, a display device includes a substrate, a first switch element including a first active layer including a first channel portion above the substrate, a first electrode at one side of the first channel portion, a second electrode at another side of the first channel portion, a gate electrode overlapping the first channel portion in a thickness direction of the substrate, and a first capacitor including a first capacitor electrode extending from a first electrode of the first switch element, and a second capacitor electrode extending from the gate electrode of the first switch element and overlapping the first capacitor electrode in the thickness direction.

The second capacitor electrode may overlap the first electrode in the thickness direction.

The display device may further include a first insulating film between the first channel portion and the gate electrode, between the first capacitor electrode and the second capacitor electrode, and between the first electrode and the second capacitor electrode.

The display device may further include a second capacitor including a third capacitor electrode and the first capacitor electrode, and a second insulating film between the third capacitor electrode and the first capacitor electrode.

The second capacitor electrode may be above the first active layer.

The substrate may include a glass material.

The display device may further include a third switch element including a first electrode connected to the second electrode of the first switch element, a second electrode configured to receive a first driving voltage, and a gate electrode configured to receive a first emission control signal.

The third switch element may further include a third active layer at a same layer as the first active layer and including the first electrode of the third switch element, the second electrode of the third switch element, and a third channel portion between the first electrode of the third switch element and the second electrode of the third switch element.

The first active layer and the third active layer may include an oxide semiconductor material.

The display device may further include a light-emitting element including a first electrode connected to the first electrode of the first switch element, a second electrode configured to receive a second driving voltage, and a light-emitting layer, a second switch element including a first electrode connected to the gate electrode of the first switch element, a second electrode configured to receive a data voltage, and a gate electrode configured to receive a write scan signal, and a fourth switch element including a first electrode connected to the first electrode of the first switch element, a second electrode configured to receive a third driving voltage, and a gate electrode configured to receive a bias scan signal.

The second switch element may further include a second active layer including the first electrode of the second switch element, the second electrode of the second switch element, and a second channel portion between the first electrode of the second switch element and the second electrode of the second switch element, wherein the fourth switch element further includes a fourth active layer at a same layer as the second active layer and including the first electrode of the fourth switch element, the second electrode of the fourth switch element, and a fourth channel portion between the first electrode of the fourth switch element and the second electrode of the fourth switch element.

The third switch element may further include a third active layer including the first electrode of the third switch element, the second electrode of the third switch element, and a third channel portion between the first electrode of the third switch element and the second electrode of the third switch element, wherein the first active layer and the third active layer are above the second active layer and the fourth active layer.

The first active layer, the second active layer, the third active layer, and the fourth active layer may include a silicon semiconductor material.

The display device may further include a third capacitor electrode between the first active layer and the second active layer, wherein the gate electrode of the second switch element and the gate electrode of the fourth switch element are at a same layer, wherein the first active layer and the third active layer are above the gate electrode of the second switch element and the gate electrode of the fourth switch element, and wherein the third capacitor electrode overlaps the first capacitor electrode in the thickness direction.

According to various embodiments of the present disclosure, an electronic device includes a processor configured to provide an image signal, a display module configured to receive the image signal from the processor and configured to display an image, and a power module configured to supply power to the display module, wherein the display module includes a substrate, a first switch element including a first active layer including a first channel portion above the substrate, a first electrode at one side of the first channel portion, a second electrode at another side of the first channel portion, and a gate electrode, and a first capacitor including a first capacitor electrode extending from a first electrode of the first switch element, and a second capacitor electrode extending from the gate electrode of the first switch element and overlapping the first capacitor electrode in a thickness direction of the substrate.

The second capacitor electrode may overlap the first electrode in the thickness direction.

The electronic device may further include a first insulating film between the first channel portion and the gate electrode, between the first capacitor electrode and the second capacitor electrode, and between the first electrode and the second capacitor electrode, a second capacitor including a third capacitor electrode and the first capacitor electrode, and a second insulating film between the third capacitor electrode and the first capacitor electrode.

According to various embodiments of the present disclosure, a manufacturing method of a display device includes arranging a semiconductor layer on an insulating film, arranging a photoresist and a mask on the semiconductor layer to distinguish a region to be doped from a region not to be doped, allowing the photoresist to react with light, injecting ions or impurities into the semiconductor layer to perform doping, and forming a gate metal layer including a capacitor electrode overlapping a region of the semiconductor layer where doping is performed, and a gate electrode overlapping a region of the semiconductor layer where no doping is performed.

The manufacturing method may further include placing a gate-insulating film between the gate metal layer and the semiconductor layer.

The gate electrode and the capacitor electrode may be physically connected.

According to the present disclosure, a display device with improved PPI may be provided by including a simplified pixel circuit that emits light concurrently or substantially simultaneously, rather than sequentially. The pixel circuit may include at least four switch elements.

According to one or more embodiments of the present disclosure, a first capacitor may be provided between a first capacitor electrode extending from a first electrode of a first transistor, and a second capacitor electrode extending from a first gate electrode. Accordingly, pixel integration may be improved, and thus a high-resolution display device may be provided.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view showing a display device according to one or more embodiments of the present disclosure;

FIG. 2 is a block diagram showing a display device according to one or more embodiments of the present disclosure;

FIG. 3 is a layout diagram illustrating an example of a display panel according to one or more embodiments of the present disclosure;

FIG. 4 is a layout diagram showing an example of the display area of FIG. 3;

FIG. 5 is a layout diagram showing another example of the display area of FIG. 3;

FIG. 6 is an equivalent circuit diagram showing a conventional pixel circuit;

FIG. 7 is an equivalent circuit diagram showing a pixel circuit according to first one or more embodiments of the present disclosure;

FIG. 8 is a modified circuit diagram showing a pixel circuit according to the first one or more embodiments of the present disclosure;

FIG. 9 is a cross-sectional view showing a partial configuration of a pixel circuit in a display panel according to the first one or more embodiments of the present disclosure;

FIG. 10 is a detailed cross-sectional view showing the pixel circuit in the display panel according to the first one or more embodiments of the present disclosure;

FIG. 11 is an equivalent circuit diagram showing a pixel circuit according to second one or more embodiments of the present disclosure;

FIG. 12 is a modified circuit diagram showing a pixel circuit according to second one or more embodiments of the present disclosure;

FIG. 13 is a cross-sectional view showing a partial configuration of a pixel circuit in a display panel according to second one or more embodiments of the present disclosure;

FIGS. 14 to 20 are cross-sectional views illustrating a method of manufacturing a display panel according to the embodiments of the present disclosure;

FIG. 21 is a perspective view illustrating a head-mounted display according to one or more embodiments of the present disclosure;

FIG. 22 is an exploded perspective view illustrating an example of the head-mounted display of FIG. 21;

FIG. 23 is a perspective view illustrating a head-mounted display according to one or more embodiments of the present disclosure;

FIG. 24 is a block diagram of an electronic device according to one or more embodiments of the present disclosure; and

FIG. 25 is schematic diagrams of electronic devices according to various embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

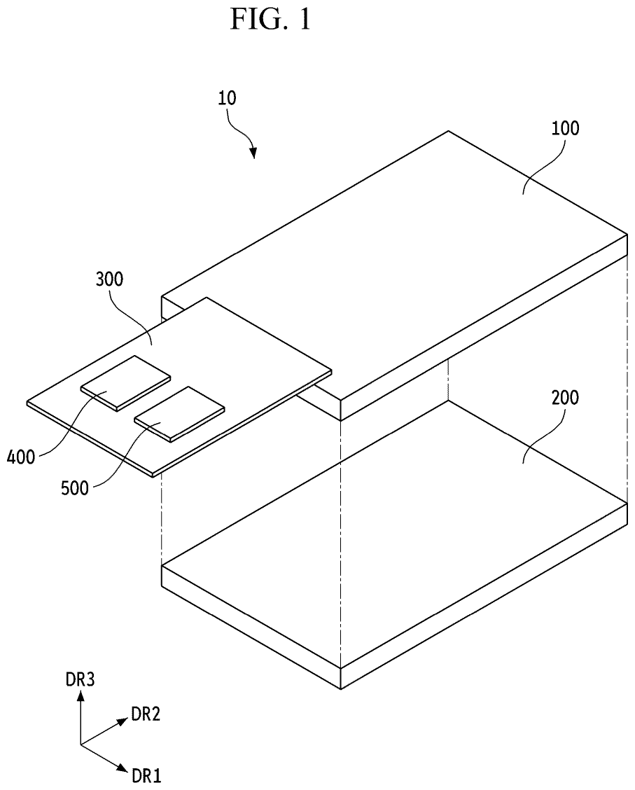

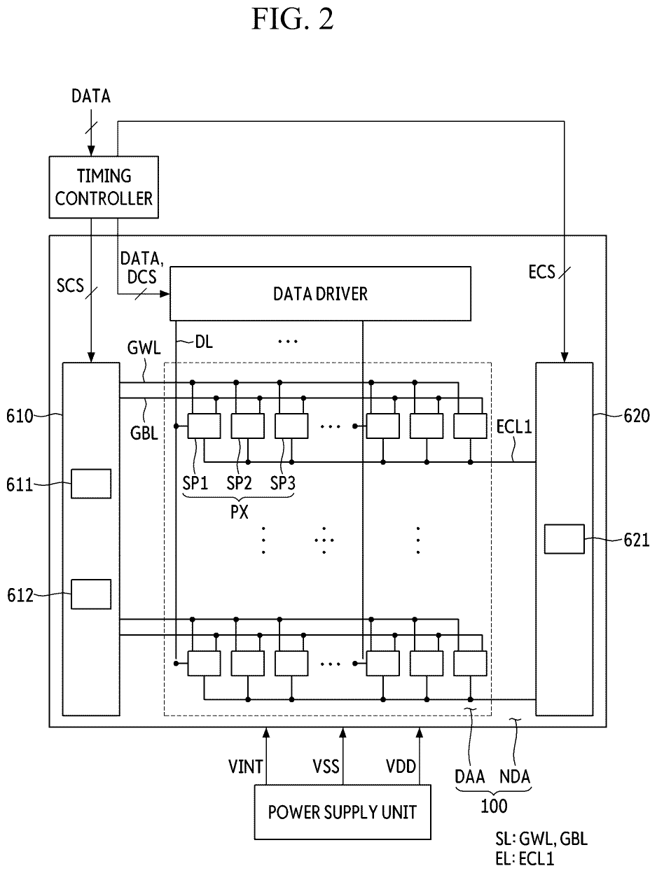

FIG. 1 is an exploded perspective view showing a display device according to one or more embodiments of the present disclosure. FIG. 2 is a block diagram showing a display device according to one or more embodiments of the present disclosure.

Referring to FIGS. 1 and 2, a display device 10 according to one or more embodiments is a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to one or more embodiments may be applied as a display unit of a television, a laptop, a monitor, a billboard, or an Internet-of-Things (IoT) terminal. Alternatively, the display device 10 according to one or more embodiments may be applied to a smart watch, a watch phone, a head-mounted display (HMD) for implementing virtual reality and augmented reality, and the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 crossing the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 includes a plurality of pixels PX, a plurality of scan lines SL, a plurality of emission control lines ECL1, a plurality of data lines DL, a scan driver 610, an emission driver 620, and a data driver 700. The display panel 100 may be divided into a display area DAA for displaying an image and a non-display area NDA for not displaying an image.

The plurality of pixels PX may be arranged in the display area DAA. The plurality of pixels PX may be arranged in a matrix form in the first direction DR1 and the second direction DR2. The plurality of scan lines SL and the plurality of emission control lines ECL1 may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of bias scan lines GBL, and the like. The plurality of emission control lines ECL1 may include a plurality of first emission control lines ECL1.

The plurality of pixels PX include a plurality of sub-pixels SP1, SP2, and SP3. The plurality of sub-pixels SP1, SP2, and SP3 may include a plurality of pixel transistors, and the plurality of pixel transistors may be arranged on a base substrate including a glass material.

Each of the sub-pixels SP1, SP2, and SP3 may be connected to one write scan line GWL, one bias scan line GBL, one first emission control line ECL1, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors.

The scan driver 610 may include a write scan signal output unit 611 and a bias scan signal output unit 612. Each of the write scan signal output unit 611 and the bias scan signal output unit 612 may receive a scan-timing control signal SCS from the timing control circuit 400. The write scan signal output unit 611 may generate write scan signals according to the scan-timing control signal SCS of the timing control circuit 400 and output them sequentially or concurrently/substantially simultaneously to the write scan lines GWL. The bias scan signal output unit 612 may generate bias scan signals according to the scan-timing control signal SCS and output them sequentially or concurrently/substantially simultaneously to the bias scan lines GBL. In the display device 10, the scan signals may be outputted concurrently or substantially simultaneously rather than sequentially to the plurality of scan lines. Accordingly, the plurality of pixels arranged in the vertical direction may emit light concurrently or substantially simultaneously rather than sequentially.

The emission driver 620 includes a first emission control driver 621. The first emission control driver 621 may receive an emission-timing control signal ECS from the timing control circuit 400. The first emission control driver 621 may generate first emission control signals according to the emission-timing control signal ECS and may sequentially or concurrently/substantially simultaneously output them to the first emission control lines ECL1. In the display device 10, the emission control signals may be outputted concurrently or substantially simultaneously rather than sequentially to the plurality of emission control lines. Thus, the plurality of pixels arranged in the vertical direction may emit concurrently or substantially simultaneously rather than sequentially.

The data driver 700 includes a plurality of data transistors. The data driver 700 may receive digital video data DATA and a data-timing control signal DCS from the timing control circuit 400. The data driver 700 converts the digital video data DATA into analog data voltages according to the data-timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface (e.g., the rear surface) of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

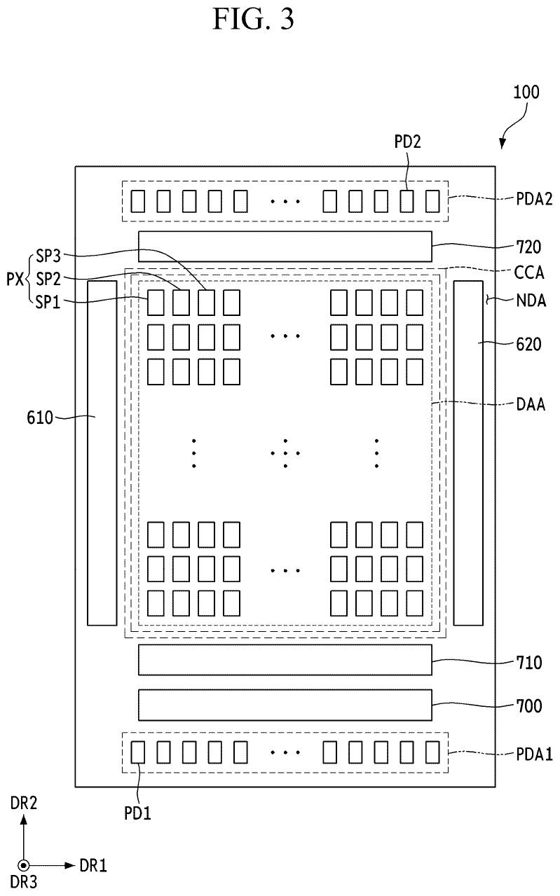

The circuit board 300 may be electrically connected to a plurality of first pads PD1 (see FIG. 3) of a first pad portion PDA1 (see FIG. 3) of the display panel 100 by using a conductive adhesive member, such as an anisotropic conductive film. The circuit board 300 may be a flexible printed circuit board with a flexible material, or a flexible film. As shown, the circuit board 300 is unfolded, but the circuit board 300 may be folded. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 3) of the first pad portion PDA1 (see FIG. 3) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan-timing control signal SCS, the emission-timing control signal ECS, and the data-timing control signal DCS for controlling the display panel 100 in response to the timing signals. The timing control circuit 400 may output the scan-timing control signal SCS to the scan driver 610, and output the emission-timing control signal ECS to the emission driver 620. The timing control circuit 400 may output the digital video data and the data-timing control signal DCS to the data driver 700.

The power supply circuit 500 may generate a plurality of panel-driving voltages according to a power voltage from the outside. For example, the power supply circuit 500 may generate a second driving voltage VSS, a first driving voltage VDD, and a third driving voltage VINT, and may supply them to the display panel 100.

Each of the timing control circuit 400 and the power supply circuit 500 may be formed as an integrated circuit (IC) and attached to one surface of the circuit board 300. In this case, the scan-timing control signal SCS, the emission-timing control signal ECS, the digital video data DATA, and the data-timing control signal DCS of the timing control circuit 400 may be supplied to the display panel 100 through the circuit board 300. Further, the second driving voltage VSS, the first driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. Each of the timing control circuit 400 and the power supply circuit 500 may be located between the data driver 700 and the first pad portion PDA1 (see FIG. 3).

FIG. 3 is a layout diagram illustrating an example of a display panel according to one or more embodiments of the present disclosure.

Referring to FIG. 3, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that assess whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection portion CCA may be a region where the cathode electrode is connected to a second driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. Alternatively, the cathode connection portion CCA may be located to surround the display area DAA to reduce or minimize a deviation in the second driving voltage VSS due to a voltage drop (IR drop) or voltage rise (IR rising) of the second electrode CAT in the display area DAA.

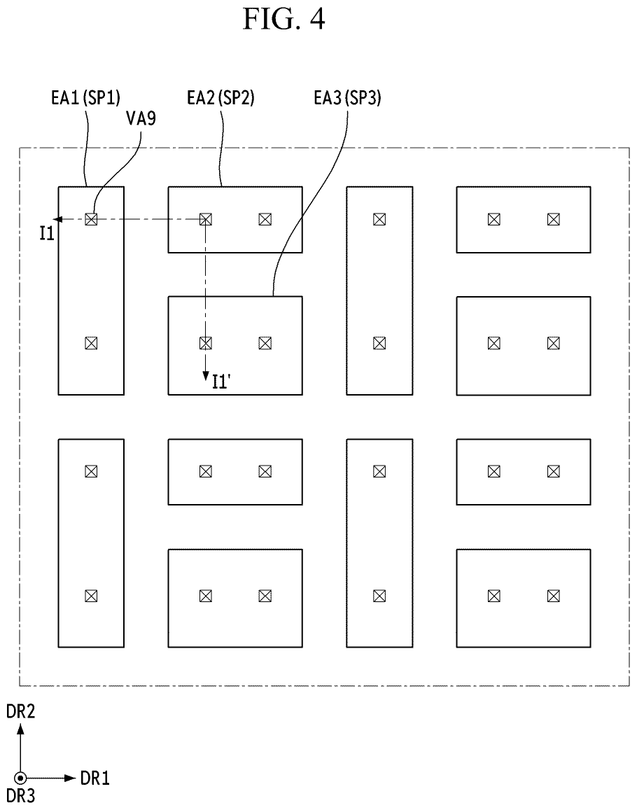

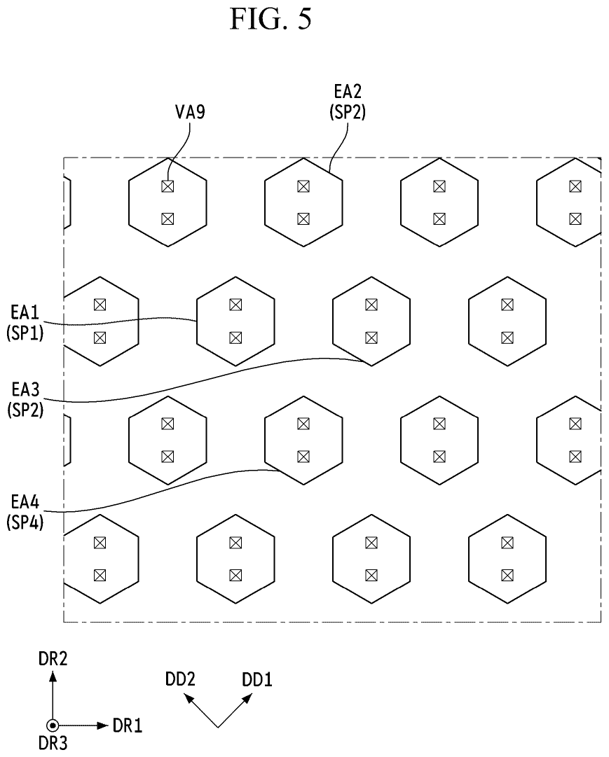

FIG. 4 is a layout diagram showing an example of the display area of FIG. 3. FIG. 5 is a layout diagram showing another example of the display area of FIG. 3.

Referring to FIGS. 4 and 5, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as shown in FIGS. 4 and 5, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 4, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 5, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to approximately 460 nm, the green wavelength band may be a wavelength band of light whose main peak wavelength is in the range of approximately 480 nm to approximately 560 nm, and the red wavelength band may be a wavelength band of light whose main peak wavelength is in the range of approximately 600 nm to approximately 750 nm.

Each of the plurality of pixels PX may include three emission areas EA1, EA2, and EA3 as shown in FIG. 4, or may include four emission areas EA1, EA2, EA3, and EA4 as shown in FIG. 5. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure (PenTile® being a registered trademark of Samsung Display Co., Ltd., Republic of Korea) in which the emission areas EA1, EA2, EA3, and EA4 are arranged in a rhombus shape, or a hexagonal structure in which the emission areas each having a hexagonal shape are arranged as shown in FIG. 5.

The circuit disclosed herein may include a plurality of transistors. The transistor may be an oxide thin-film transistor (TFT) including an oxide semiconductor or a low temperature poly silicon (LTPS) TFT including LTPS.

The transistor is a three-electrode switch element including a gate, source, and drain. The source is an electrode that supplies carriers to the transistor. In the transistor, carriers begin to flow from the source. The drain is an electrode through which carriers move out of the transistor. In the transistor, carriers flow from the source to the drain.

In the case of an N-channel MOSFET (NMOS) transistor, the carriers are electrons, and thus the source voltage is lower than the drain voltage so that electrons may flow from the source to the drain. In the NMOS transistor, the current flows from the drain to the source. In the case of a P-channel MOSFET (PMOS) transistor, the carriers are holes, and thus the source voltage is higher than the drain voltage so that holes may flow from the source to the drain. In the PMOS transistor, because the holes flow from the source to the drain, the current flows from the source to the drain. It should be noted that the source and drain of a transistor are not fixed. For example, the source and drain may be changed according to the applied voltage. Therefore, the present disclosure is not limited by the source and drain of the transistor. In the following description, the source and drain of the transistor will be referred to as a first electrode and a second electrode, respectively.

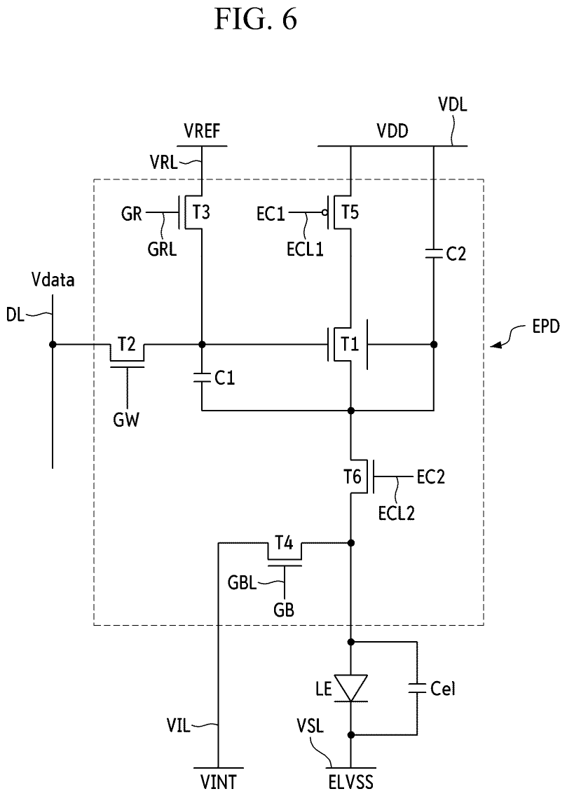

FIG. 6 is an equivalent circuit diagram showing a conventional pixel circuit.

The pixel circuits EPD may be electrically connected to the light-emitting element LE. The pixel circuits EPD may be electrically connected to a first power line VDL that transmits the first driving voltage VDD. The light-emitting elements LE may be electrically connected to a second power line VSL that transmits the second driving voltage VSS different from the first driving voltage VDD. The second driving voltage VSS may have a lower voltage level than that of the first driving voltage VDD.

The anode electrode of the light-emitting element LE may be electrically connected to the pixel circuit EPD, and the cathode electrode of the light-emitting element LE may be electrically connected to the second power line VSL. The pixel circuit EPD may be electrically connected to a data line DL that transmits a data signal Vdata, a reference voltage line VRL that transmits a reference voltage VREF, and an initialization voltage line VIL that transmits an initialization voltage VINT.

The pixel circuit EPD may be electrically connected to the write scan line GWL that transmits a write scan signal GW, a reset control line GRL that transmits a reset control signal GR, the bias scan line GBL that transmits a bias scan signal GB, the first emission control line ECL1 that transmits a first emission control signal EC1, and a second emission control line ECL2 that transmits a second emission control signal EC2.

The pixel circuit EPD may include a first transistor (e.g., a first switch element, in the claims) T1 for generating a driving current of the light-emitting element LE, two or more transistors T2 to T6 electrically connected to the first transistor T1, and one or more capacitors C1 and C2.

A second transistor (e.g., second switch element, in the claims) T2 may be electrically connected between the gate electrode of the first transistor T1 and the data line DL. The second transistor T2 may be turned on by the write scan signal GW of the write scan line GWL. When the second transistor T2 is turned on, the data signal Vdata of the data line DL may be transmitted to the gate electrode of the first transistor T1.

When the voltage difference between the gate electrode of the first transistor T1 and a first electrode (e.g., the source electrode) of the first transistor T1 is equal to greater than the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata.

A third transistor (e.g., third switch element, in the claims) T3 may be electrically connected between the gate electrode of the first transistor T1 and the reference voltage line VRL. The third transistor T3 may be turned on by the reset control signal GR of the reset control line GRL. When the third transistor T3 is turned on, the potential of the gate electrode of the first transistor T1 may be initialized to the reference voltage VREF of the reference voltage line VRL.

A fourth transistor (e.g., fourth switch element, in the claims) T4 may be electrically connected between the light-emitting element LE and the initialization voltage line VIL. The fourth transistor T4 may be turned on by the bias scan signal GB of the bias scan line GBL. When the fourth transistor T4 is turned on, the potential of the anode electrode of the light-emitting element LE may be initialized to the initialization voltage VINT of the initialization voltage line VIL.

The fifth transistor T5 may be electrically connected between the second electrode of the first transistor T1 and the first power line VDL. The fifth transistor T5 may be turned on by the first emission control signal EC1 of the first emission control line ECL1.

The sixth transistor T6 may be electrically connected between the first electrode of the first transistor T1 and the light-emitting element LE. The sixth transistor T6 may be turned on by the second emission control signal EC2 of the second emission control line ECL2.

When the fifth transistor T5 and the sixth transistor T6 are turned on, the first transistor T1 and the light-emitting element LE are connected in series between the first driving voltage VDD and the second driving voltage VSS so that the drain-source current of the first transistor T1 generated to have a magnitude corresponding to the data signal Vdata may be transmitted to the light-emitting element LE. Accordingly, the light-emitting element LE may emit light having a luminance corresponding to the data signal Vdata.

The first capacitor C1 may be electrically connected between the gate electrode of the first transistor T1 and the first electrode of the first transistor T1. Accordingly, the first capacitor C1 may be charged with the data signal Vdata applied to the gate electrode of the first transistor T1, and the turn-on of the first transistor T1 may be maintained for a selected period due to the voltage charged in the first capacitor C1.

A second capacitor C2 may be electrically connected between the first electrode of the first transistor T1 and the first power line VDL. The voltage of the first capacitor C1 may correspond to the potential difference between the gate electrode of the first transistor T1 and the first electrode of the first transistor T1, may be changed by the data signal Vdata, and may be divided by the second capacitor C2. Accordingly, the threshold voltage of the first transistor T1 may be compensated.

According to one or more embodiments, the first transistor T1 may include the gate electrode facing one surface of a channel portion, and an additional gate electrode facing the other surface of the channel portion. The channel portion of the first transistor T1 may be located between the gate electrode and the additional gate electrode.

The gate electrode of the first transistor T1 may be electrically connected to the second transistor T2. The additional gate electrode of the first transistor T1 may be electrically connected to the first electrode of the first transistor T1.

Accordingly, when the data signal Vdata is applied to the gate electrode of the first transistor T1 such that the first transistor T1 is in a turned-on state, at least a part of the channel portion of the first transistor T1, which is adjacent to the gate electrode, is activated, while the remaining part of the channel portion of the first transistor T1, which is adjacent to the additional gate electrode, may not be activated.

Therefore, the electron mobility in the channel portion of the first transistor T1 may be decreased, and the slope of a current curve representing a relationship between the drain-source current and the voltage of the gate electrode of the first transistor T1 may become gentle. Accordingly, a driving voltage range of the first transistor T1 may be widened, which may facilitate luminance control.

According to one or more embodiments, the first transistor T1 may be an NMOS transistor and at least some of the second to sixth transistors T2 to T6 may be PMOS transistors. For example, the fifth transistor T5 may be a PMOS transistor, and the second transistor T2, third transistor T3, fourth transistor T4, and sixth transistor T6 may be NMOS transistors.

In one or more embodiments, the first transistor T1 may be an oxide TFT including an oxide semiconductor. Compared to the LTPS TFTs, the oxide TFTs have similar transistor threshold voltages between the pixels. Therefore, if an oxide TFT is used as a driving transistor, uniformity related to the threshold voltage characteristics of the driving transistor may be improved across the entire screen.

Because the channel layer of the oxide TFT is manufactured based on an amorphous semiconductor, a threshold voltage difference may exist between the driving transistors when viewed across the whole display panel. However, the threshold voltage difference between the pixels in a local region is insignificant, which may improve the uniformity described above. In the case of an LTPS TFT, due to the characteristics of polycrystalline silicon, the threshold voltage difference between adjacent driving transistors may increase according to a grain boundary position.

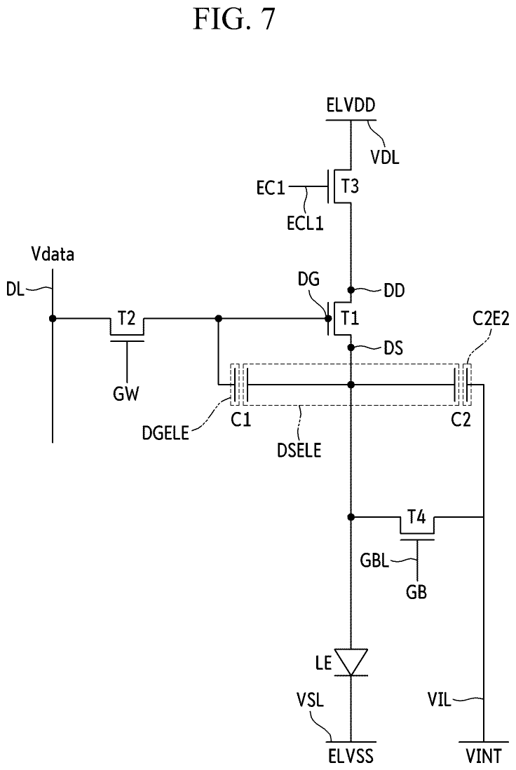

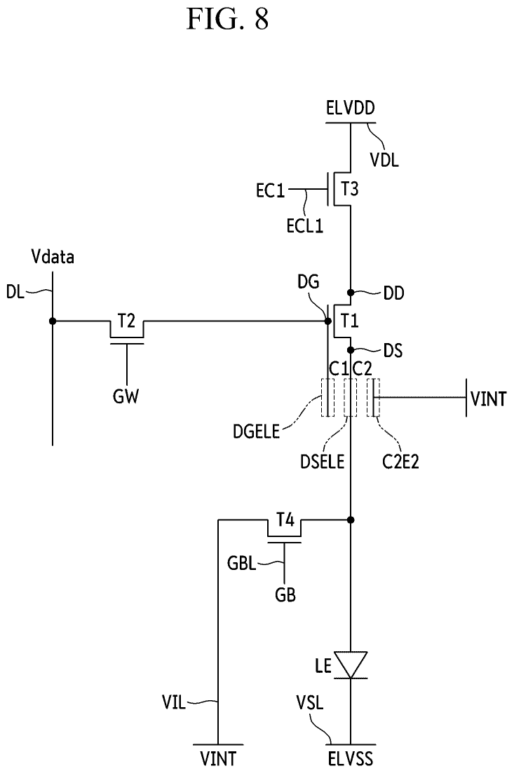

FIG. 7 is an equivalent circuit diagram showing a pixel circuit according to first one or more embodiments of the present disclosure. FIG. 8 is a modified circuit diagram showing a pixel circuit according to the first one or more embodiments of the present disclosure.

Referring to FIGS. 7 and 8, the pixel circuit may be electrically connected to the light-emitting element LE. The pixel circuit may be electrically connected to a first power line VDL that transmits the first driving voltage VDD. The light-emitting elements LE may be electrically connected to a second power line VSL that transmits the second driving voltage VSS, which is different from the first driving voltage VDD. The second driving voltage VSS may have a lower voltage level than that of the first driving voltage VDD.

The anode electrode of the light-emitting element LE may be electrically connected to the pixel circuit, and the cathode electrode of the light-emitting element LE may be electrically connected to the second power line VSL. The pixel circuit may be electrically connected to the data line DL that transmits the data signal Vdata, and to the initialization voltage line VIL that transmits the initialization voltage VINT.

The pixel circuit may be electrically connected to the write scan line GWL that transmits the write scan signal GW, the bias scan line GBL that transmits the bias scan signal GB, and the first emission control line ECL1 that transmits the first emission control signal EC1.

The pixel circuit may include the first transistor T1 for generating a driving current of the light-emitting element LE, two or more transistors T2 to T4 electrically connected to the first transistor T1, and the first capacitor C1 and the second capacitor C2.

The second transistor T2 may be electrically connected between the gate electrode of the first transistor T1 and the data line DL. The second transistor T2 may be turned on by the write scan signal GW of the write scan line GWL. When the second transistor T2 is turned on, the data signal Vdata of the data line DL may be transmitted to the gate electrode of the first transistor T1.

When the voltage difference between the gate electrode of the first transistor T1 and a first electrode (e.g., the source electrode) of the first transistor T1 is equal to greater than the threshold voltage of the first transistor T1 due to the data signal Vdata applied to the gate electrode of the first transistor T1, the first transistor T1 may be turned on. However, this is the case where the first transistor T1 is an NMOS transistor. In the case where the first transistor T1 is a PMOS transistor, the first transistor T1 may be turned on when the voltage difference is equal to or less than the threshold voltage of the first transistor T1. When the first transistor T1 is turned on, the drain-source current of the first transistor T1 may be generated to have a magnitude corresponding to the data signal Vdata.

The fourth transistor T4 may be electrically connected between the light-emitting element LE and the initialization voltage line VIL. The fourth transistor T4 may be turned on by the bias scan signal GB of the bias scan line GBL. When the fourth transistor T4 is turned on, the potential of the anode electrode of the light-emitting element LE may be initialized to the initialization voltage VINT of the initialization voltage line VIL.

The third transistor T3 may be electrically connected between the second electrode of the first transistor T1 and the first power line VDL. The third transistor T3 may be turned on by the first emission control signal EC1 of the first emission control line ECL1.

When the third transistor T3 is turned on, the first transistor T1 and the light-emitting element LE are connected in series between the first driving voltage VDD and the second driving voltage VSS so that the drain-source current of the first transistor T1 generated to have a magnitude corresponding to the data signal Vdata may be transmitted to the light-emitting element LE. Accordingly, the light-emitting element LE may emit light having a luminance corresponding to the data signal Vdata.

The first transistor T1 includes a first electrode connected to the anode electrode of the light-emitting element, a second electrode connected to the third transistor T3, and a gate electrode connected to the second transistor T2. In the case where the first transistor T1 is an NMOS transistor, the carriers are electrons, and thus the electrons move from a first node DS where the first electrode is located to a second node DD where the second electrode is located, and the current flows from the second node DD to the first node DS. A data voltage may be supplied from the second transistor T2 to a third node DG where the gate electrode is located.

The first capacitor C1 may include a first capacitor electrode DSELE connected to the first node DS, and a first capacitor electrode DGELE connected to the third node DG.

The first capacitor electrode DSELE may be an extension electrode extending from the first electrode of the first transistor T1. The first capacitor electrode DSELE may be physically connected to the first electrode of the first transistor T1. The potential of the first capacitor electrode DSELE may be the first node DS.

The first capacitor electrode DGELE may be an extension electrode extending from the gate electrode of the first transistor T1. The first capacitor electrode DGELE may be physically connected to the gate electrode of the first transistor T1. The potential of the first capacitor electrode DGELE may be the third node DG.

The first capacitor C1 may be electrically connected between the gate electrode and the first electrode of the first transistor T1, and may be charged with the data signal Vdata applied to the gate electrode of the first transistor T1. Due to the voltage charged in the first capacitor C1, the turn-on of the first transistor T1 may be maintained for a selected period.

The second capacitor C2 may include the first capacitor electrode DSELE connected to the first node DS, and a third capacitor electrode C2E2 connected to the initialization voltage line VIL. The second capacitor C2 may be electrically connected between the first node DS of the first transistor T1 and the initialization voltage line VIL.

For example, in the light emission, a gate-source voltage Vgs of the first transistor T1 may satisfy the following equations:

$$Vgs = ( 1 - {C}^{′} ) \times ( Vdata - Vref ) + Vth$$

$${C}^{′} = C 1 / C 1 + C 2$$

If C2 is 0, C′ becomes 1. Then, (1−C′) becomes 0 in the above equation, resulting in Vgs=Vth. Therefore, the second capacitor C2 may be suitable for the gate-source voltage Vgs of the first transistor T1 to change according to the data voltage Vdata.

In the pixel circuit, in one or more embodiments, the first to fourth transistors T1, T2, T3, and T4 may all be implemented as NMOS transistors. In addition, in one or more embodiments, the first transistor T1 and the third transistor T3 may be oxide TFTs including an oxide semiconductor, and the second transistor T2 and the fourth transistor T4 may be LTPS TFTs including a polycrystalline silicon semiconductor.

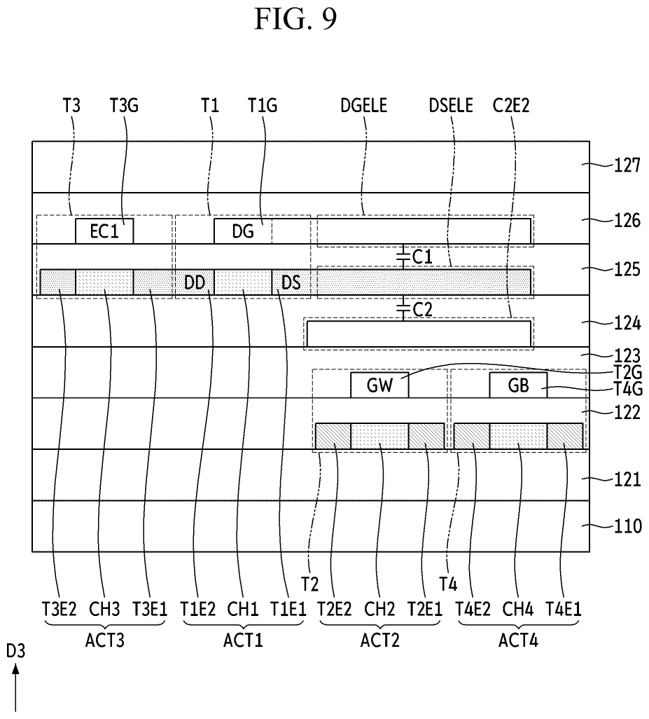

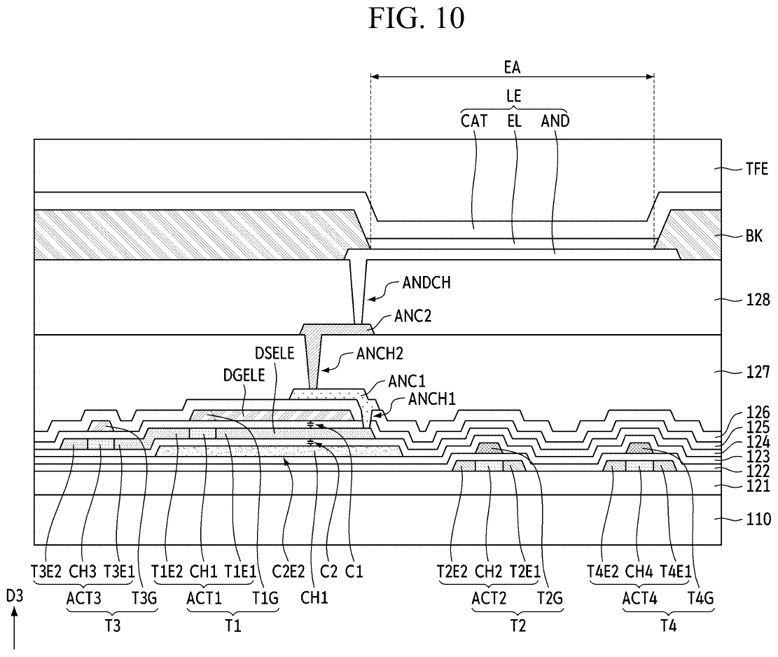

FIG. 9 is a cross-sectional view showing a partial configuration of a pixel circuit in a display panel according to the first one or more embodiments of the present disclosure. FIG. 10 is a detailed cross-sectional view showing the pixel circuit in the display panel according to the first one or more embodiments of the present disclosure.

Referring to FIGS. 9 and 10, the display panel may include a substrate 110, a buffer film 121, a first gate-insulating film 122, a second gate-insulating film 123, a first interlayer insulating film 124, a third gate-insulating film 125, a second interlayer insulating film 126, a first planarization film 127, and a second planarization film 128.

A first semiconductor layer may be located on the buffer film 121. The first gate-insulating film 122 may cover the first semiconductor layer. A first gate metal layer may be located on the first gate-insulating film 122. The second gate-insulating film 123 may cover the first gate metal layer. A second gate metal layer may be located on the second gate-insulating film 123. The first interlayer insulating film 124 may cover the second gate metal layer. A second semiconductor layer may be located on the first interlayer insulating film 124. The third gate-insulating film 125 may cover the second semiconductor layer. A third gate metal layer may be located on the third gate-insulating film 125. The second interlayer insulating film 126 may cover the third gate metal layer.

The substrate 110 may include an insulating material, such as polymer resin or glass. The substrate 110 may include a glass material. The substrate 110 may include polyimide. In this case, the substrate 110 may be a flexible substrate, which can be bent, folded, and/or rolled.

The buffer film 121 may be formed as a silicon nitride layer, a silicon oxynitride layer, a silicon oxide layer, a titanium oxide layer, or an aluminum oxide layer.

The first semiconductor layer may include a silicon semiconductor, such as polycrystalline silicon, monocrystalline silicon, low-temperature polycrystalline silicon, and amorphous silicon. The first semiconductor layer may include a second active layer ACT2 and a fourth active layer ACT4. The second active layer ACT2 may include a first electrode T2E1, a second channel portion CH2, and a second electrode T2E2 of the second transistor T2. The fourth active layer ACT4 may include a first electrode T4E1, a fourth channel portion CH4, and a second electrode T4E2 of the fourth transistor T4.

The first electrode T2E1 and the second electrode T2E2 of the second transistor T2, and the first electrode T4E1 and the second electrode T4E2 of the fourth transistor T4, may be formed by doping the first semiconductor layer with ions or impurities. The doped first semiconductor layer may have conductivity.

The second active layer ACT2 may overlap a second gate electrode T2G, to which the write scan signal GW is applied, in the third direction DR3. The first electrode T2E1 and the second electrode T2E2 of the second transistor T2 may not overlap (e.g., may be separated from, in plan view) the second gate electrode T2G in the third direction DR3. The second channel portion CH2 may overlap the second gate electrode T2G in the third direction DR3.

The fourth active layer ACT4 may overlap a fourth gate electrode T4G, to which the bias scan signal GB is applied, in the third direction DR3. The first electrode T4E1 of the fourth transistor T4 and the second electrode T4E2 of the fourth transistor T4 may not overlap the fourth gate electrode T4G in the third direction DR3. The fourth channel portion CH4 may overlap the fourth gate electrode T4G in the third direction DR3.

The first gate-insulating film 122 may be formed as an inorganic film, for example, a silicon nitride layer, a silicon oxynitride layer, a silicon oxide layer, a titanium oxide layer, or an aluminum oxide layer.

The first gate metal layer may be formed as a single layer or multiple layers containing any one of molybdenum (Mo), aluminum (Al), chromium (Cr), gold (Au), titanium (Ti), nickel (Ni), neodymium (Nd), or copper (Cu) or an alloy thereof.

The second gate-insulating film 123 may be formed as an inorganic film, for example, a silicon nitride layer, a silicon oxynitride layer, a silicon oxide layer, a titanium oxide layer, or an aluminum oxide layer.

The second gate metal layer including the third capacitor electrode C2E2 may be located on the second gate-insulating film 123. The third capacitor electrode C2E2 may constitute the second capacitor C2 together with the first capacitor electrode DSELE. The second gate metal layer may be formed as a single layer or multiple layers containing any one of molybdenum (Mo), aluminum (Al), chromium (Cr), gold (Au), titanium (Ti), nickel (Ni), neodymium (Nd), or copper (Cu) or an alloy thereof.

The first interlayer insulating film 124 may be formed as an inorganic film, for example, a silicon nitride layer, a silicon oxynitride layer, a silicon oxide layer, a titanium oxide layer, or an aluminum oxide layer.

The second semiconductor layer may be located on the first interlayer insulating film 124. The second semiconductor layer may include an oxide semiconductor. The second semiconductor layer may include a first active layer ACT1 and a third active layer ACT3. The first active layer ACT1 may include a first electrode T1E1, a first channel portion CH1, and a second electrode T1E2 of the first transistor T1. The third active layer ACT3 may include a first electrode T3E1, a third channel portion CH3, and a second electrode T3E2 of the third transistor T3.

In one or more embodiments, the first semiconductor layer may include a polycrystalline silicon semiconductor material and the second semiconductor layer may include an oxide semiconductor material.

The first electrode T1E1 and the second electrode T1E2 of the first transistor T1, and the first electrode T3E1 and the second electrode T3E2 of the third transistor T3, may be formed by doping the second semiconductor layer with ions or impurities. The doped second semiconductor layer may have conductivity.

The first active layer ACT1 may overlap a first gate electrode T1G, to which the data signal is applied, in the third direction DR3. The first electrode T1E1 and the second electrode T1E2 of the first transistor T1 may not overlap the first gate electrode T1G in the third direction DR3. The first channel portion CH1 may overlap the first gate electrode T1G in the third direction DR3.

The third active layer ACT3 may overlap the third gate electrode T3G, to which the first emission control signal EC1 is applied, in the third direction DR3. The first electrode T3E1 and the second electrode T3E2 of the third transistor T3 may not overlap the third gate electrode T3G in the third direction DR3. The third channel portion CH3 may overlap the third gate electrode T3G in the third direction DR3.

The second capacitor electrode DGELE may extend from the first gate electrode T1G while being physically connected to the first gate electrode T1G. The first capacitor electrode DSELE may extend from the first electrode T1E1 of the first transistor T1 while being physically connected to the first electrode T1E1 of the first transistor T1. The first capacitor electrode DSELE and the second capacitor electrode DGELE may constitute the first capacitor C1. The first capacitor electrode DSELE and the second capacitor electrode DGELE may overlap each other in the third direction DR3. In addition, the third capacitor electrode C2E2 may overlap the first electrode T1E1 of the first transistor T1 in the third direction DR3. The second capacitor electrode DGELE may be located above the first active layer ACT1.

In the embodiments of the present disclosure, the first capacitor C1 may be formed between the second capacitor electrode DGELE extending from the first gate electrode T1G and the first capacitor electrode DSELE extending from the first electrode T1E1 of the first transistor T1. Accordingly, pixel integration may be improved, and thus a high-resolution display device may be provided. In this case, the second capacitor electrode DGELE may be located above the first active layer ACT1.

In one or more embodiments, the third gate-insulating film 125 (or a first insulating film) may be located between the first gate electrode T1G and the first channel portion CH1, between the first capacitor electrode DSELE and the second capacitor electrode DGELE, and between the first electrode T1E1 of the first transistor T1 and the second capacitor electrode DGELE.

The third gate-insulating film 125 may be formed as an inorganic film, for example, a silicon nitride layer, a silicon oxynitride layer, a silicon oxide layer, a titanium oxide layer, or an aluminum oxide layer.

The third gate metal layer including the second capacitor electrode DGELE, the first gate electrode T1G, and the third gate electrode T3G may be formed as a single layer or multiple layers including any one of molybdenum (Mo), aluminum (Al), chromium (Cr), gold (Au), titanium (Ti), nickel (Ni), neodymium (Nd), or copper (Cu), or an alloy thereof.

The second interlayer insulating film 126 may be formed as an inorganic film, for example, a silicon nitride layer, a silicon oxynitride layer, a silicon oxide layer, a titanium oxide layer, or an aluminum oxide layer.

The first planarization film 127 may be located on the second interlayer insulating film 126. The first planarization film 127 may be formed as an organic film, such as acryl resin, epoxy resin, phenolic resin, polyamide resin, polyimide resin and the like.

Referring to FIG. 10, a first anode connection electrode ANC1 may be located on the second interlayer insulating film 126, and a second anode connection electrode ANC2 may be located on the first planarization film 127. The first anode connection electrode ANC1 may be electrically connected to the first electrode T1E1 of the first transistor T1 through a first anode connection contact hole ANCH1 formed in the third gate-insulating film 125 and in the second interlayer insulating film 126. In other words, the first anode connection electrode ANC1 may be electrically connected to the first capacitor electrode DSELE through the first anode connection contact hole ANCH1.

The second planarization film 128 located on the first planarization film 127 may be formed as an organic film, such as acryl resin, epoxy resin, phenolic resin, polyamide resin, polyimide resin, or the like.

The second anode connection electrode ANC2 located between the first planarization film 127 and the second planarization film 128 may be electrically connected to the first anode connection electrode ANC1 through a second anode connection contact hole ANCH2 formed in the first planarization film 127. The first anode connection electrode ANC1 and the second anode connection electrode ANC2 may be formed as a single layer or multiple layers containing any one of molybdenum (Mo), aluminum (Al), chromium (Cr), gold (Au), titanium (Ti), nickel (Ni), neodymium (Nd), or copper (Cu) or an alloy thereof.

The light-emitting element LE including an anode electrode AND, a light-emitting layer EL, and a cathode electrode CAT may be located on the second planarization film 128. The anode electrode AND may be electrically connected to the second anode connection electrode ANC2 through an anode contact hole ANDCH formed in the second planarization film 128. In one or more embodiments, the first anode connection electrode ANC1 and the second anode connection electrode ANC2 may be configured as one anode connection electrode. In this case, the first planarization film 127 and the second planarization film 128 may also be configured as one planarization film.

In a top emission structure in which light is emitted toward the cathode electrode CAT when viewed with respect to the light-emitting layer EL, the anode electrode AND may include a metal material having high reflectivity, such as a stacked structure (Ti/Al/Ti) of aluminum (Al) and titanium (Ti), a stacked structure (ITO/Al/ITO) of Al and ITO, an APC alloy, a stacked structure (ITO/APC/ITO) of an APC alloy and ITO, or the like. The APC alloy is an alloy of silver (Ag), palladium (Pd), and copper (Cu).

The bank BK may be formed on the second planarization film 128 to partition the anode electrode AND, thereby defining the emission area EA. The emission area EA represents a region where the anode electrode AND, the light-emitting layer EL and the cathode electrode CAT are stacked sequentially and holes from the anode electrode AND and electrons from the cathode electrode CAT are coupled to each other in the light-emitting layer EL to emit light. The bank BK may cover the edge of the anode electrode AND. The bank BK may be formed as an organic film, such as acryl resin, epoxy resin, phenolic resin, polyamide resin, polyimide resin, and the like.

The light-emitting layer EL may be formed on the anode electrode AND. The light-emitting layer EL may include an organic material to emit light in a selected color. For example, the light-emitting layer EL includes a hole-transporting layer, an organic material layer, and an electron-transporting layer.

The cathode electrode CAT may be formed on the light-emitting layer EL. The cathode electrode CAT may cover the light-emitting layer EL. The cathode electrode CAT may be a common layer commonly formed across all emission areas EA including the illustrated emission area EA. A capping layer may be formed on the cathode electrode CAT.

In the top emission structure, the cathode electrode CAT may include transparent conductive oxide (TCO), such as indium tin oxide (ITO) and indium zinc oxide (IZO) capable of transmitting light or a semi-transmissive conductive material, such as magnesium (Mg), silver (Ag), or an alloy of magnesium (Mg) and silver (Ag). When the cathode electrode CAT includes a semi-transmissive conductive material, the light output efficiency can be increased due to a micro-cavity effect.

An encapsulation layer TFE may be located on the cathode electrode CAT. The encapsulation layer TFE may include at least one inorganic film to reduce or prevent oxygen or moisture from permeating into the light-emitting element LE. In addition, the encapsulation layer TFE may include at least one organic film to protect the light-emitting element LE from foreign substances, such as dust. For example, the encapsulation layer TFE may include a plurality of inorganic films and a single organic film, but embodiments of the present disclosure are not limited thereto. The inorganic film may be formed as multiple films in which one or more inorganic films of a silicon nitride layer, a silicon oxynitride layer, a silicon oxide layer, a titanium oxide layer and an aluminum oxide layer are alternately stacked. The organic film may include acryl resin, epoxy resin, phenolic resin, polyamide resin, polyimide resin or the like.

In some embodiments, a filling layer, a sealant, and an encapsulation substrate may be arranged in place of the encapsulation layer TFE. In this case, the encapsulation substrate may be an insulating substrate containing an insulating material, such as glass or plastic. The filling layer may be an air layer in a vacuum state, but is not limited thereto. The sealant may be located in a non-display area of the display panel while surrounding the display area.

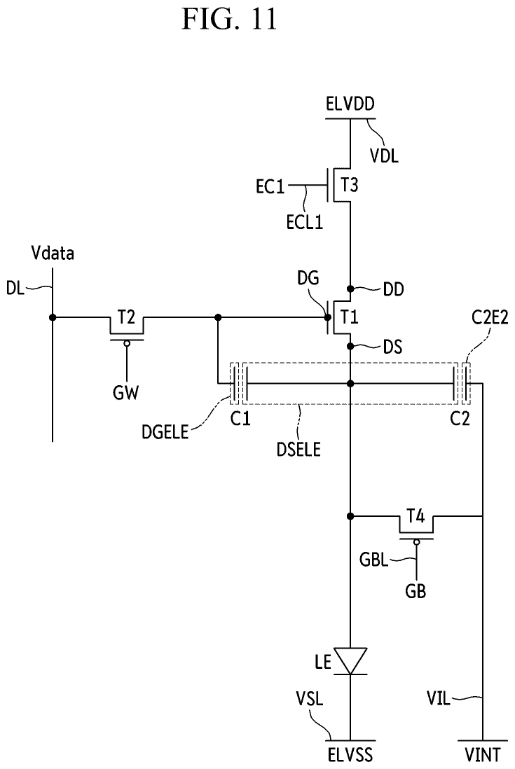

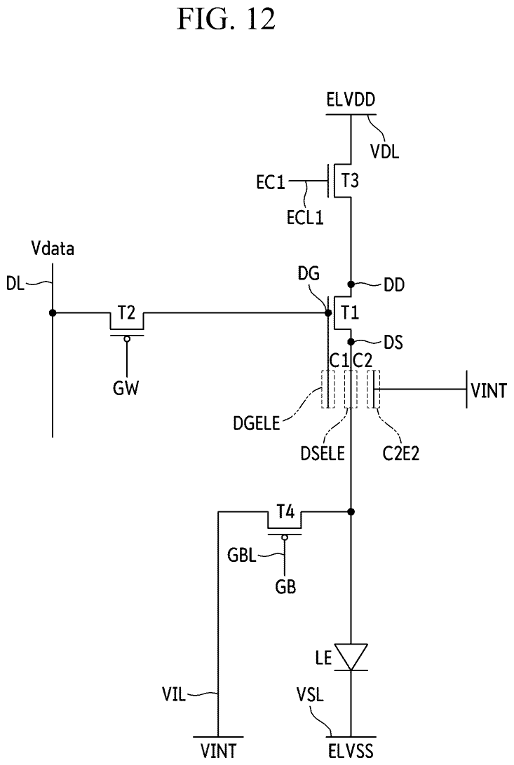

FIG. 11 is an equivalent circuit diagram showing a pixel circuit according to second one or more embodiments of the present disclosure. FIG. 12 is a modified circuit diagram showing a pixel circuit according to second one or more embodiments of the present disclosure.

Referring to FIGS. 11 and 12, the embodiments differ from the aforementioned first one or more embodiments in that, the second transistor T2 and the fourth transistor T4 are implemented as PMOS transistors, and the first transistor T1 and the third transistor T3 are implemented as NMOS transistors. If the second transistor T2 and the fourth transistor T4 are implemented as PMOS transistors, there may be an advantage in terms of power efficiency of the display device. Except for these differences, like reference numerals are given to like parts having substantially the same function as those of the first one or more embodiments, and repeated descriptions are omitted.

In addition, the first transistor T1 and the third transistor T3 may be LTPS TFTs including a polycrystalline silicon semiconductor, and the second transistor T2 and the fourth transistor T4 may also be LTPS TFTs including a polycrystalline silicon semiconductor. This is different from the first one or more embodiments in which the first transistor T1 and the third transistor T3 are oxide TFTs including an oxide semiconductor.

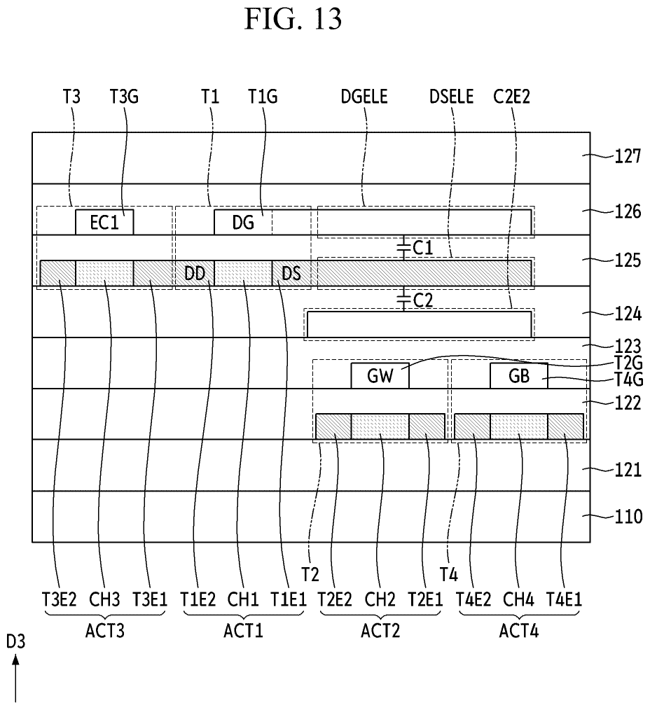

FIG. 13 is a cross-sectional view showing a partial configuration of a pixel circuit in a display panel according to second one or more embodiments of the present disclosure.

Referring to FIG. 13, compared to the aforementioned first one or more embodiments, the second semiconductor layer may include a silicon semiconductor, such as polycrystalline silicon, monocrystalline silicon, low-temperature polycrystalline silicon, and/or amorphous silicon. The second semiconductor layer may include the first active layer ACT1 and the third active layer ACT3. The first active layer ACT1 and the third active layer ACT3 are different from those in the first one or more embodiments including an oxide semiconductor. If the second semiconductor layer includes a silicon semiconductor, there may be an advantage in terms of manufacturing cost of the display device. Except for this, like reference numerals are given to like parts having substantially the same function as those of the first one or more embodiments, and repeated descriptions are omitted.

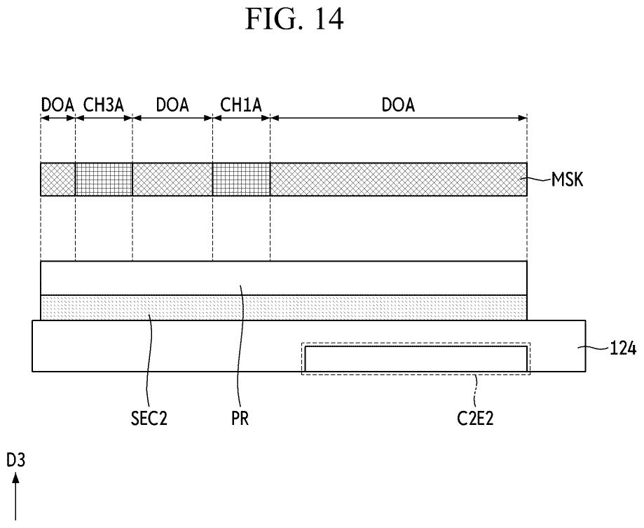

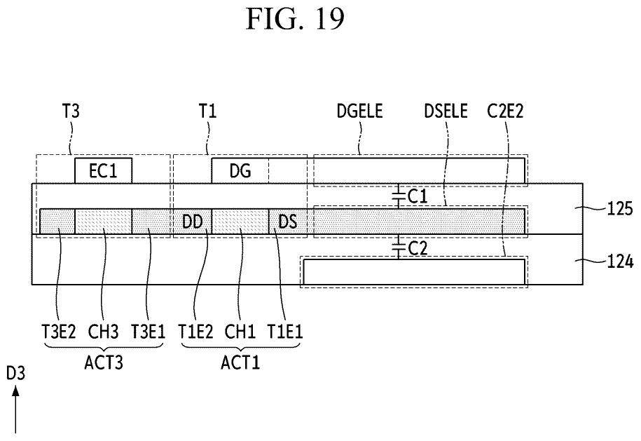

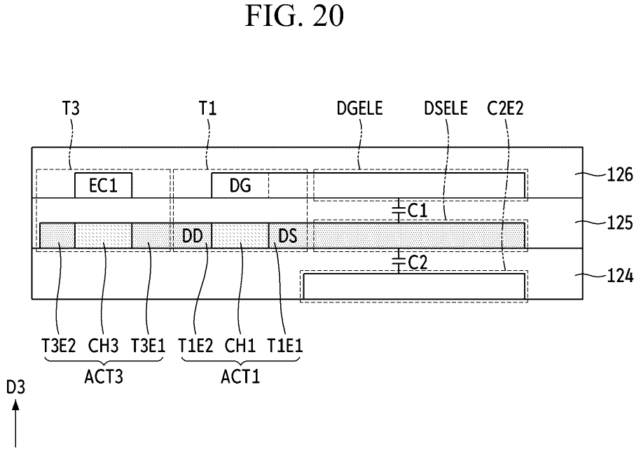

FIGS. 14 to 20 are cross-sectional views illustrating a method of manufacturing a display panel according to the embodiments of the present disclosure.

Referring to FIG. 14, an operation of dividing the second semiconductor layer SEC2 formed on the first interlayer insulating film 124 into a region to be doped and a region not to be doped may be performed. A photoresist PR located on the second semiconductor layer SEC2 may be divided into a region DOA to be doped and a region not to be doped by a mask MSK. As the mask MSK, a half-tone mask MSK may be used, but the embodiments of the present disclosure are not limited thereto. The mask MSK may be divided into regions corresponding to the region DOA to be doped, a region CH1A where the first channel portion CH1 is to be formed, and a region CH3A where the third channel portion CH3 is to be formed.

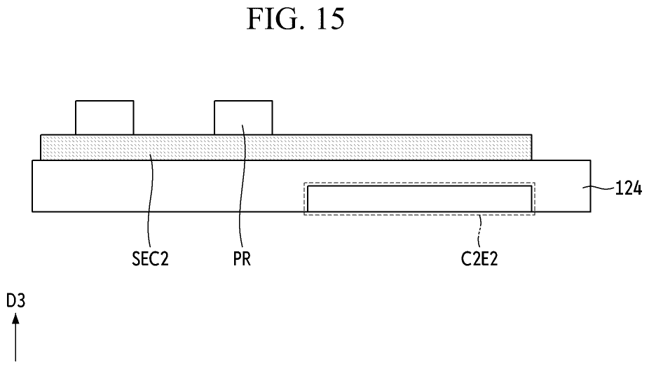

Referring to FIG. 15, an operation of photosensitizing the photoresist PR through the mask MSK may be performed. For example, assuming that it is of a positive type, the photoresist PR corresponding to the region DOA to be doped may be completely dissolved by receiving light. Accordingly, only a region corresponding to the region CH1A where the first channel portion CH1 is to be formed and a region corresponding to the region CH3A where the third channel portion CH3 is to be formed may exist in the photoresist PR.

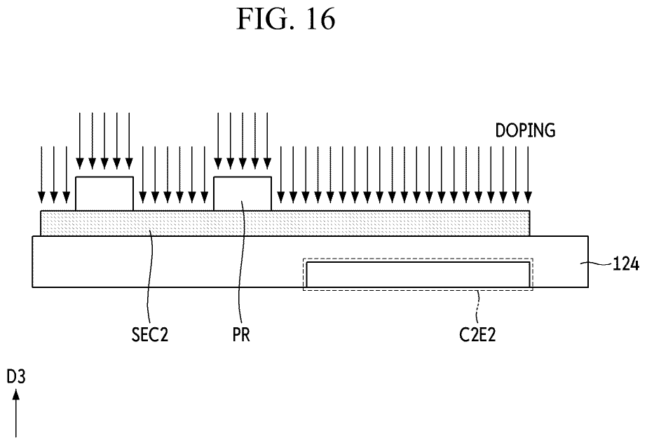

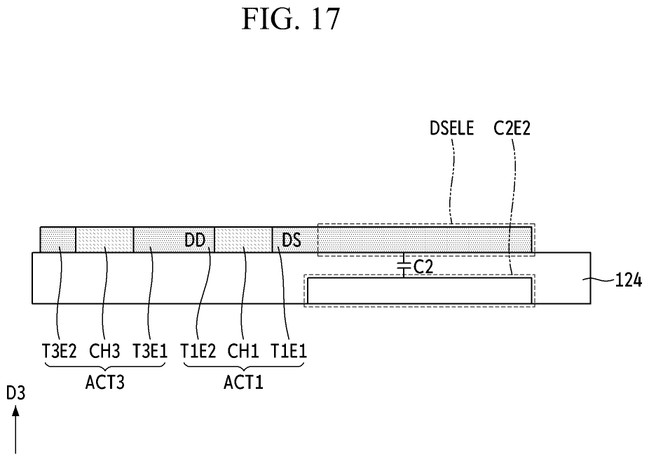

Referring to FIGS. 16 and 17, a doping operation may be performed with the photoresist PR located. The first electrode of the first transistor T1 and the first capacitor electrode DSELE extending from the first electrode may be formed by doping ions or impurities. The doped second semiconductor layer SEC2 may have conductivity. Accordingly, the first active layer ACT1 and the third active layer ACT3 may be formed. The first capacitor electrode DSELE and the third capacitor electrode C2E2 may constitute the second capacitor C2.

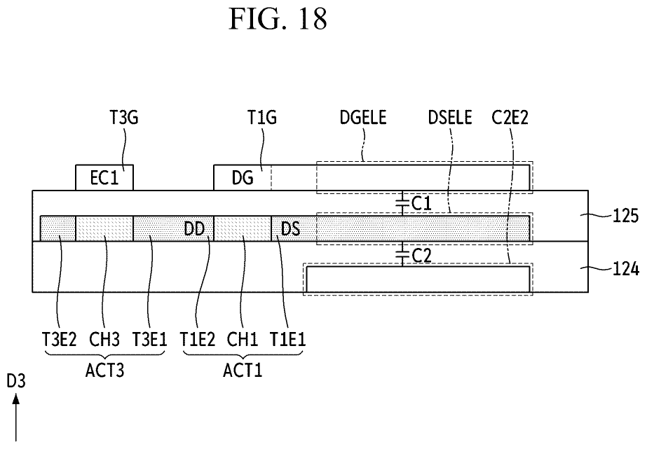

Referring to FIGS. 18 to 20, an operation of locating the third gate-insulating film 125 to cover the second semiconductor layer SEC2 may be performed, and then an operation of locating the third gate metal layer on the third gate-insulating film 125 may be performed. The third gate electrode T3G may overlap the third channel portion CH3, and the first gate electrode T1G may overlap the first channel portion CH1. The first gate electrode T1G may include the second capacitor electrode DGELE, which may overlap the first capacitor electrode DSELE. The first capacitor electrode DSELE and the second capacitor electrode DGELE may constitute the first capacitor C1.

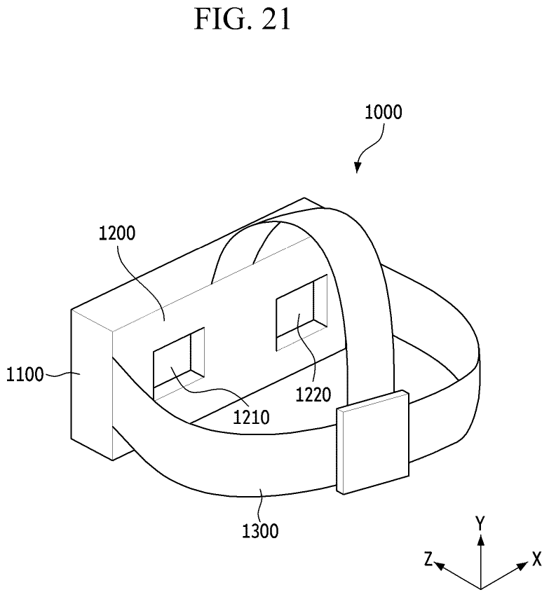

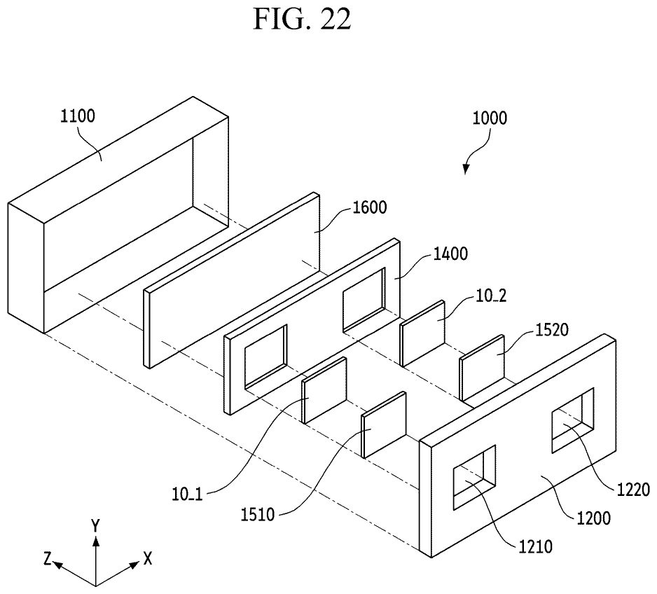

FIG. 21 is a perspective view illustrating a head-mounted display according to one or more embodiments of the present disclosure. FIG. 22 is an exploded perspective view illustrating an example of the head-mounted display of FIG. 21.

Referring to FIGS. 21 and 22, a head-mounted display 1000 according to one or more embodiments of the present disclosure includes a first display device 10_1, a second display device 10_2, a display device housing 1100, a display device housing 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described above, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and may transmit the digital video data DATA to the first display device 10_1 and the second display device 10_2 through the connector.

The control circuit board 1600 may transmit the digital video data DATA corresponding to a left-eye image for the user's left eye to the first display device 10_1, and may transmit the digital video data DATA corresponding to a right-eye image for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The display device housing 1200 is located to cover one open surface of the display device housing 1100. The display device housing 1200 may include the first eyepiece 1210 at which the user's left eye is located and the second eyepiece 1220 at which the user's right eye is located. FIGS. 21 and 22 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

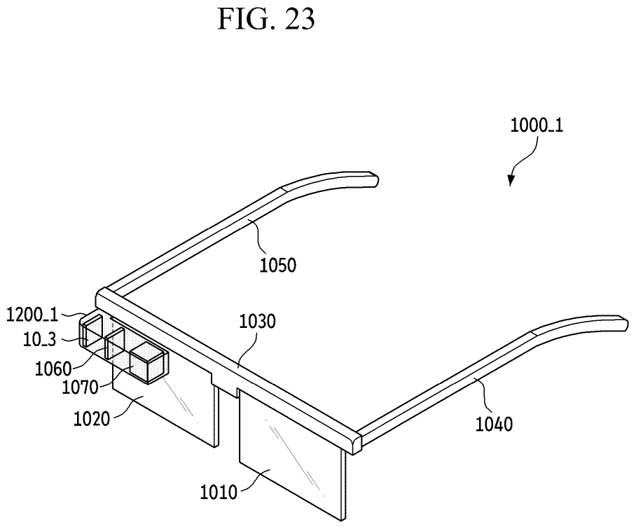

The head-mounted band 1300 serves to secure the display device housing 1100 to the user's head such that the first eyepiece 1210 and the second eyepiece 1220 of the display device housing 1200 remain located on the user's left and right eyes, respectively. When the display device housing 1200 is implemented to be lightweight and compact, the head-mounted display 1000 may be provided with, as shown in FIG. 23, an eyeglass frame instead of the head-mounted band 1300.

FIG. 23 is a perspective view illustrating a head-mounted display according to one or more embodiments of the present disclosure.

Referring to FIG. 23, a head-mounted display 1000_1 according to one or more embodiments may be an eyeglasses-type display device in which a display device housing 1200_1 is implemented in a lightweight and compact manner. The head-mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 10_3 and a real image seen through the right eye lens 1020 are combined.

FIG. 23 illustrates that the display device housing 1200_1 is located at the right end of the support frame 1030, but the present disclosure is not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

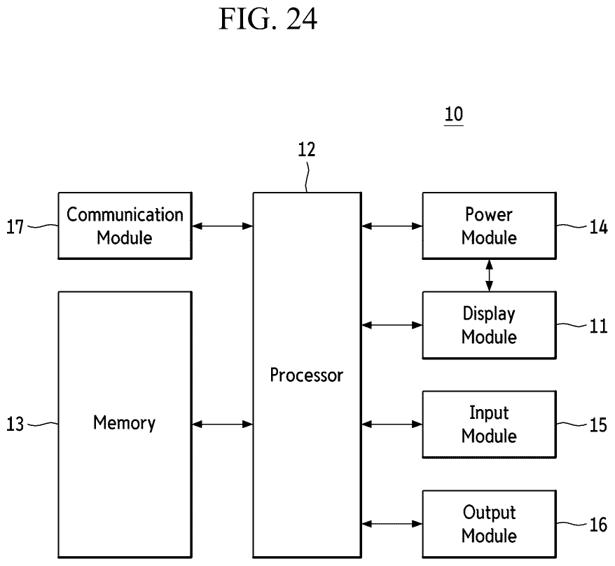

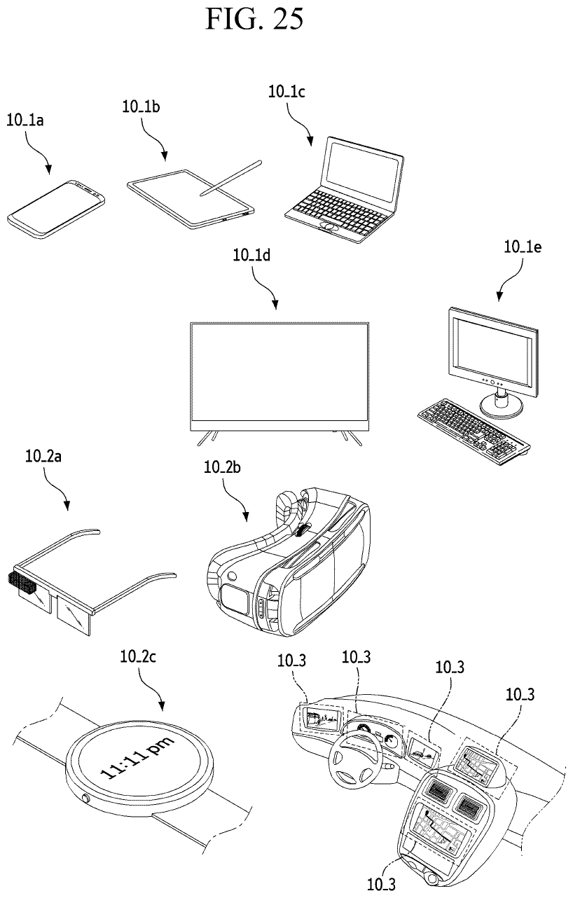

FIG. 24 is a block diagram of an electronic device according to one or more embodiments of the present disclosure. FIG. 25 is schematic diagrams of electronic devices according to various embodiments of the present disclosure.

Referring to FIG. 24, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information suitable for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device. The power module 14 may include a power conversion module. The power conversion module may convert the power supplied by the power supply module to generate a power suitable for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device may include the display module 11, whereas the processor 12, the memory 13 and the power module 14 may be provided in the form of other devices in the electronic device, other than the display device.

Referring to FIG. 25, various electronic devices to which display devices according to embodiments of the present disclosure are applied may include an electronic device for displaying images, such as a smartphone 10_1a, a tablet PC 10_1b, a laptop 10_1c, a TV 10_1d, and a desk monitor 10_1e. In addition, various electronic devices to which the display devices according to the embodiments of the present disclosure are applied may include a wearable electronic device including a display module, such as smart glasses 10_2a, a head-mounted display 10_2b, and a smart watch 10_2c, a vehicle electronic device 10_3 including a display module, such as a center fascia, and a dashboard of an automobile, a center information display (CID) placed on the dashboard, a room mirror display, and the like.

Although embodiments of the disclosure have been described above with reference to the accompanying drawings, it will be understood by those having ordinary skill in the technical field to which the disclosure belongs that the disclosure may be practiced in other forms without altering the technical idea or essential features of the disclosure. It should therefore be understood that the embodiments described above are only examples in all respects and are not intended to be limiting.

What is claimed is:

1. A display device comprising:
a substrate;
a first switch element comprising:
a first active layer comprising a first channel portion above the substrate;
a first electrode at one side of the first channel portion;
a second electrode at another side of the first channel portion;
a gate electrode overlapping the first channel portion in a thickness direction of the substrate; and
a first capacitor comprising a first capacitor electrode extending from a first electrode of the first switch element, and a second capacitor electrode extending from the gate electrode of the first switch element and overlapping the first capacitor electrode in the thickness direction.

2. The display device of claim 1, wherein the second capacitor electrode overlaps the first electrode in the thickness direction.

3. The display device of claim 1, further comprising a first insulating film between the first channel portion and the gate electrode, between the first capacitor electrode and the second capacitor electrode, and between the first electrode and the second capacitor electrode.

4. The display device of claim 1, further comprising:
a second capacitor comprising a third capacitor electrode and the first capacitor electrode; and
a second insulating film between the third capacitor electrode and the first capacitor electrode.

5. The display device of claim 1, wherein the second capacitor electrode is above the first active layer.

6. The display device of claim 1, wherein the substrate comprises a glass material.

7. The display device of claim 1, further comprising a third switch element comprising a first electrode connected to the second electrode of the first switch element, a second electrode configured to receive a first driving voltage, and a gate electrode configured to receive a first emission control signal.

8. The display device of claim 7, wherein the third switch element further comprises a third active layer at a same layer as the first active layer and comprising the first electrode of the third switch element, the second electrode of the third switch element, and a third channel portion between the first electrode of the third switch element and the second electrode of the third switch element.

9. The display device of claim 8, wherein the first active layer and the third active layer comprise an oxide semiconductor material.

10. The display device of claim 7, further comprising:
a light-emitting element comprising a first electrode connected to the first electrode of the first switch element, a second electrode configured to receive a second driving voltage, and a light-emitting layer;
a second switch element comprising a first electrode connected to the gate electrode of the first switch element, a second electrode configured to receive a data voltage, and a gate electrode configured to receive a write scan signal; and
a fourth switch element comprising a first electrode connected to the first electrode of the first switch element, a second electrode configured to receive a third driving voltage, and a gate electrode configured to receive a bias scan signal.

11. The display device of claim 10, wherein the second switch element further comprises a second active layer comprising the first electrode of the second switch element, the second electrode of the second switch element, and a second channel portion between the first electrode of the second switch element and the second electrode of the second switch element, and
wherein the fourth switch element further comprises a fourth active layer at a same layer as the second active layer and comprising the first electrode of the fourth switch element, the second electrode of the fourth switch element, and a fourth channel portion between the first electrode of the fourth switch element and the second electrode of the fourth switch element.

12. The display device of claim 11, wherein the third switch element further comprises a third active layer comprising the first electrode of the third switch element, the second electrode of the third switch element, and a third channel portion between the first electrode of the third switch element and the second electrode of the third switch element, and
wherein the first active layer and the third active layer are above the second active layer and the fourth active layer.

13. The display device of claim 12, wherein the first active layer, the second active layer, the third active layer, and the fourth active layer comprise a silicon semiconductor material.

14. The display device of claim 12, further comprising a third capacitor electrode between the first active layer and the second active layer,
wherein the gate electrode of the second switch element and the gate electrode of the fourth switch element are at a same layer,
wherein the first active layer and the third active layer are above the gate electrode of the second switch element and the gate electrode of the fourth switch element, and
wherein the third capacitor electrode overlaps the first capacitor electrode in the thickness direction.

15. An electronic device comprising:
a processor configured to provide an image signal;
a display module configured to receive the image signal from the processor and configured to display an image; and
a power module configured to supply power to the display module,
wherein the display module comprises:
a substrate;
a first switch element comprising:
a first active layer comprising a first channel portion above the substrate;
a first electrode at one side of the first channel portion;
a second electrode at another side of the first channel portion; and
a gate electrode; and
a first capacitor comprising a first capacitor electrode extending from a first electrode of the first switch element, and a second capacitor electrode extending from the gate electrode of the first switch element and overlapping the first capacitor electrode in a thickness direction of the substrate.

16. The electronic device of claim 15, wherein the second capacitor electrode overlaps the first electrode in the thickness direction.

17. The electronic device of claim 15, further comprising:
a first insulating film between the first channel portion and the gate electrode, between the first capacitor electrode and the second capacitor electrode, and between the first electrode and the second capacitor electrode;
a second capacitor comprising a third capacitor electrode and the first capacitor electrode; and
a second insulating film between the third capacitor electrode and the first capacitor electrode.

18. A manufacturing method of a display device, comprising:
arranging a semiconductor layer on an insulating film;
arranging a photoresist and a mask on the semiconductor layer to distinguish a region to be doped from a region not to be doped;
allowing the photoresist to react with light;
injecting ions or impurities into the semiconductor layer to perform doping; and
arranging a gate metal layer comprising a capacitor electrode overlapping a region of the semiconductor layer where doping is performed, and a gate electrode overlapping a region of the semiconductor layer where no doping is performed.

19. The manufacturing method of claim 18, further comprising placing a gate-insulating film between the gate metal layer and the semiconductor layer.

20. The manufacturing method of claim 18, wherein the gate electrode and the capacitor electrode are physically connected.
